(19) United States
(12) Patent Application Publication
(10) Pub. No.: US 2026/0143848 A1
(43) Pub. Date: May 21, 2026

(54) NANOWIRE-BASED SENSORS

(71) Applicant: WOBER TECH INC., Dover, DE (US)

(72) Inventor: Munib WOBER, Wakefield, MA (US)

(21) Appl. No.: 19/119,387

(22) PCT Filed: Oct. 16, 2023
(86) PCT No.: PCT/US2023/076938

§ 371 Date: Apr. 8, 2025

Related U.S. Application Data
(60) Provisional application No. 63/379,495, filed on Oct. 14, 2022.
(60) Provisional application No. 63/380,747, filed on Oct. 24, 2022.
(60) Provisional application No. 63/382,175, filed on Nov. 3, 2022.
(60) Provisional application No. 63/490,414, filed on Mar. 15, 2023.
(60) Provisional application No. 63/502,494, filed on May 16, 2023.

(51) Int. Cl. H10F 77/14; H10F 39/12; H10F 77/30

(52) U.S. Cl. CPC H10F 77/1437; H10F 39/12; H10F 77/334

(57) ABSTRACT

Nanowire-based sensors may include an array of nanowires attached to a substrate. The nanowires may have a cladding and are configured to selectively direct incident light into the substrate to interact with surface plasmons at a metal layer on the surface of the substrate. Nanowire-based sensors may include an array of nanowires coupled to their respective closest neighbors. The nanowires may be arranged in a spiral, a half coil, a full coil in the order of increase radii.

### CROSS-REFERENCE TO RELATED APPLICATIONS

The disclosure herein relates U.S. Provisional Application No. 63/379,495, filed on Oct. 14, 2022; U.S. Provisional Application No. 63/380,747, filed on Oct. 24, 2022; U.S. Provisional Application No. 63/382,175, filed on Nov. 3, 2022; U.S. Provisional Application No. 63/490,414, filed on Mar. 15, 2023; and U.S. Provisional Application No. 63/502,494, filed on May 16, 2023. The entire disclosures of each of these provisional applications are incorporated by reference.

### BACKGROUND

Surface plasmon resonance (SPR) may be used for multiple detection of biomolecules, real-time monitoring interactions of multiplexed chemical and biological analytes (e.g., interactions between RNAs, DNAs or proteins and a wide variety of ligands or cofactors.

SPR is a charge-density oscillation that exists at a two media interface with dielectric constants of opposite signs, for example, a dielectric (e.g., buffer, air or water) and a metal (e.g., silver or gold), upon interaction with plane polarized light. This process leads to changes in the refractive index of the dielectric medium. The change in the refractive index of the dielectric medium gives rise to a modification of the propagation constant of the surface plasmons, altering the resonance condition between the interacting optical wave and the surface plasmons. A biosensor based on SPR may be in the prism-coupled configuration, including a metal (e.g., gold) film, a (e.g., glass) prism, a light source and a detector in which the metal film is placed at the interface between two dielectric media. One dielectric medium is the prism with a higher refractive index and the other is air or liquid sample with a lower refractive index. A laser beam overpasses the prism and excites the surface plasmons. The reflected light on the surface of the metal film is measured by the detector to produce the SPR spectrum. Gold may be a suitable material for the metal film due to its high density of conduction band electrons, the combination of optical wavelengths and reflectance angles, immovability in physiological buffer conditions and easy functionalization by thiolated biomolecules.

Conventional color imaging devices, such as digital cameras, use pixelated monochromatic image sensors, such as charge-coupled devices (CCDs), in connection with three different color filters to generate color images. The conventional imaging devices includes a lens, filters and photodetectors. The three different color filters typically transmit broadband portions of the visible spectrum centered on a red wavelength, a green wavelength and a blue wavelength, for example, 650 nm, 532 nm and 473 nm, respectively. Each filter is sufficiently broadband such that the three filters cover the entire visible spectrum. Each “pixel” of the image sensor comprises three “sub-pixels,” each of which detects the amount of light transmitted through an associated one of the three colored filters.

Conventional “multispectral imaging” uses more than three filters with narrower bandwidths than conventional RGB imaging and can therefore extend the capabilities of the human eye. The portion of the electromagnetic spectrum covered by the filters may extend into the ultraviolet and/or the infrared, thereby providing more information than is acquired with conventional visible spectrum imaging devices. Multispectral has many applications in both military and civilian applications, such as remote sensing, vegetation mapping, non-invasive biological imaging, face recognition and food quality control. Conventional multispectral imaging devices include devices that use motorized filter wheels, multiple image sensors, and/or multilayer dielectric interference filters.

### SUMMARY

Disclosed herein is a device comprising: a substrate of a first dielectric material; nanowires attached to a first surface of the substrate, the nanowires being in a periodic array; a first metal layer on the first surface; a second metal layer on a second surface of the substrate, opposite the first surface. At least one of the nanowires comprises a core of a semiconductor and a cladding of a second dielectric material. The cladding surrounds the core. The nanowires and the substrate are in direct physical contact.

In an aspect, the first dielectric material is an oxide.

In an aspect, the second dielectric material is an oxide.

In an aspect, the core in cylindrical in shape.

In an aspect, the cladding has a uniform thickness in a radial direction of the core.

In an aspect, the nanowires extend in a direction perpendicular to the first surface.

In an aspect, the device is configured to receive light into the core and to direct the light through the core into the substrate; and the light in the substrate interacts with surface plasmons in the first metal layer.

In an aspect, the nanowires are attached to the first surface and the second surface.

In an aspect, the first metal layer extends to a sidewall of the cladding.

Disclosed herein is a device comprising: a substrate with a recess into a first surface of the substrate; nanowires inside the recess and extending from a bottom of the recess; a conformal coating on the bottom of the recess, a sidewall of the nanowires and a top surface of the nanowires; and a light blocking layer at the bottom of the recess among the nanowires and over the conformal coating. The conformal coating and the nanowires form a p-n junction at an interface between the conformal coating and the nanowires.

In an aspect, the nanowires are coextensive with a depth of the recess.

In an aspect, the p-n junction is continuous and is conformal to the nanowires.

In an aspect, the device further comprises dielectric filled isolation trenches in the substrate, and the dielectric filled isolation trenches are configured to prevent crosstalk among the nanowires.

In an aspect, a lattice of the nanowires and a lattice of the substrate are continuous.

In an aspect, the substrate is a semiconductor.

In an aspect, conformal coating is on a sidewall of the recess.

In an aspect, the conformal coating is a dielectric material.

In an aspect, the conformal coating is aluminum oxide.

In an aspect, the light blocking layer is not on the sidewall of the nanowires or the top surface of the nanowires.

In an aspect, the device further comprises an electric contact to the substrate.

In an aspect, the electric contact comprises molybdenum oxide.

In an aspect, the device further comprises bump contacts corresponding to the nanowires on a second surface of the substrate opposite the first surface.

In an aspect, the bump contacts comprise LiF.

In an aspect, the nanowires are arranged in an array of unit cells.

In an aspect, the nanowires of different unit cells are not coupled.

In an aspect, the nanowires of a same unit cell are not coupled.

In an aspect, at least one of the unit cells encompasses a first nanowire of a radius R1, a second nanowire of a radius R2, a third nanowire of a radius R3 and a fourth nanowire of a radius R4; R4>R3>R2>R1; the first nanowire, the second nanowire, the third nanowire, and the fourth nanowire are arranged at the vertexes of a square.

In an aspect, (1) the first nanowire is closest to the second nanowire and the fourth nanowire but not to the third nanowire; (2) the second nanowire is closest to the first nanowire and the third nanowire but not to the fourth nanowire; (3) the third nanowire is closest to the second nanowire and the fourth nanowire but not to the first nanowire; and (4) the fourth nanowire is closest to the first nanowire and the third nanowire but not to the second nanowire.

In an aspect, (R2−R1)=(R3−R2).

In an aspect, R1=10 nm, R2=15 nm, R3=20 nm and R4=25 nm.

In an aspect, R1=30 nm, R2=45 nm, R3=50 nm and R4=70 nm.

In an aspect, R1=10 nm, R2=12.5 nm, R3=14 nm and R4=20 nm.

In an aspect, at least one of the unit cells encompasses nine nanowire: a 1^{st} nanowire of a radius R1, a 2^{nd} nanowire of a radius R2, a 3^{rd} nanowire of a radius R3, a 4^{th} nanowire of a radius R4, a 5^{th} nanowire of a radius R5, a 6^{th} nanowire of a radius R6, a 7^{th} nanowire of a radius R7, an 8^{th} nanowire of a radius R8 and a 9^{th} nanowire of a radius R9; R9>R8>R7>R6>R5>R4>R3>R2>R1; and the 1^{st} nanowire, the 2^{nd} nanowire, the 3^{rd} nanowire, the 4^{th} nanowire, the 5^{th} nanowire, the 6^{th} nanowire, the 7^{th} nanowire, the 8^{th} nanowire and the 9^{th} nanowire are in a square 3-by-3 grid.

In an aspect, (1) the 1^{st} nanowire is closest to the 2^{nd} and 6^{th} nanowires but not to the others of the nine nanowires; (2) the 2^{nd} nanowire is closest to the 1^{st}, 3^{rd} and 5^{th} nanowires but not to the others of the nine nanowires; (3) the 3^{rd} nanowire is closest to the 2^{nd} and 4^{th} nanowires but not to the others of the nine nanowires; (4) the 4^{th} nanowire is closest to the 3^{rd}, 5^{th} and 9^{th} nanowires but not to the others of the nine nanowires; (5) the 5^{th} nanowire is closest to the 2^{nd}, 4^{th}, 6^{th} and 8^{th} nanowires but not to the others of the nine nanowires; (6) the 6^{th} nanowire is closest to the 1^{st}, 5^{th} and 7^{th} nanowires but not to the others of the nine nanowires; (7) the 7^{th} nanowire is closest to the 6^{th} and 8^{th} nanowires but not to the others of the nine nanowires; (8) the 8^{th} nanowire is closest to the 5^{th}, 7^{th} and 9^{th} nanowires but not to the others of the nine nanowires; (9) the 9^{th} nanowire is closest to the 6^{th} and 8^{th} nanowires but not to the others of the nine nanowires.

In an aspect, (1) the 1^{st} nanowire is closest to the 2^{nd} and 8^{th} nanowires but not to the others of the nine nanowires; (2) the 2^{nd} nanowire is closest to the 1^{st}, 3^{rd} and 9^{th} nanowires but not to the others of the nine nanowires; (3) the 3^{rd} nanowire is closest to the 2^{nd} and 4^{th} nanowires but not to the others of the nine nanowires; (4) the 4^{th} nanowire is closest to the 3^{rd}, 5^{th} and 9^{th} nanowires but not to the others of the nine nanowires; (5) the 5^{th} nanowire is closest to the 4^{th} and 6^{th} nanowires but not to the others of the nine nanowires; (6) the 6^{th} nanowire is closest to the 5^{th}, 7^{th} and 9^{th} nanowires but not to the others of the nine nanowires; (7) the 7^{th} nanowire is closest to the 6^{th} and 8^{th} nanowires but not to the others of the nine nanowires; (8) the 8^{th} nanowire is closest to the 1^{st}, 7^{th} and 9^{th} nanowires but not to the others of the nine nanowires; (9) the 9^{th} nanowire is closest to the 2^{nd}, 4^{th}, 6^{th} and 8^{th} nanowires but not to the others of the nine nanowires.

In an aspect, (R2−R1)=(R3−R2)=(R4−R3)=(R5−R4)=(R6−R5)=(R7−R6)=(R8−R7).

In an aspect, R1=30 nm, R2=35 nm, R3=40 nm, R4=45 nm, R5=50 nm, R6=55 nm, R7=60 nm, R8=65 nm and R9=70 nm.

### BRIEF DESCRIPTION OF FIGURES

FIG. 1 schematically shows a cross-sectional view of a device.

FIG. 2 schematically shows a perspective view of the device of FIG. 1.

FIG. 3 schematically shows a cross-sectional view of a device.

FIG. 4 schematically shows a perspective view of the device of FIG. 2.

FIG. 5 shows the electric field component along the z axis inside the substrate of the device of FIG. 1.

FIG. 6 shows the electric field component along the y axis inside the substrate of the device of FIG. 1.

FIG. 7 shows the output spectrum from the substrate of the device of FIG. 1.

FIG. 8 schematically shows a cross-sectional view of a device.

FIG. 9 shows the electric field component along the y axis inside the substrate of the device of FIG. 8.

FIG. 10 schematically an absorption spectrum of uncoupled nanowires and an absorption spectrum of coupled nanowires.

FIG. 11 shows an example of an array of nanowires of a radius of 30 nm, nanowires of a radius of 40 nm and nanowires of a radius of 50 nm, in a triangular lattice.

FIG. 12 shows the absorption spectra of the nanowires in the array of FIG. 11.

FIG. 13 shows the absorption spectra of the nanowires in another triangular lattice that is the same as the triangular lattice in FIG. 11, except the radii of the nanowires are 40 nm, 45 nm and 50 nm.

FIG. 14 shows an example of an array of nanowires of a radius of 30 nm, nanowires of a radius of 40 nm and nanowires of a radius of 50 nm, in a square lattice.

FIG. 15A shows an example of an array of nanowires of a radius of 30 nm, nanowires of a radius of 40 nm, nanowires of a radius of 50 nm, nanowires of a radius of 60 nm, and nanowires of a radius of 70 nm, in a square lattice.

FIG. 15B shows an alternative example of an array 220 of nanowires 221 of a radius of 30 nm, nanowires 222 of a radius of 40 nm, nanowires 223 of a radius of 50 nm, nanowires 224 of a radius of 60 nm, and nanowires 225 of a radius of 70 nm, in a square lattice.

FIG. 16 schematically shows a cross-section of a portion of a device.

FIG. 17 shows that the device of FIG. 16 may be connected to a signal processing circuit using interconnects.

FIG. 18 shows that the device of FIG. 16 may be connected to an array of pixel transistors and a signal processing circuit.

FIG. 19 shows a top view of a unit cell in an embodiment.

FIG. 20 shows the absorption spectra of the nanowires of radii of 10 nm and 15 nm in the unit cell of FIG. 19.

FIG. 21 shows a top view of a unit cell in an embodiment.

FIG. 22 shows the absorption spectra of the nanowires of radii of 30 nm, 40 nm and 50 nm in the unit cell of FIG. 21.

FIG. 23 shows a top view of a unit cell in an embodiment.

FIG. 24 shows the absorption spectra of the nanowires of radii of 30 nm, 35 nm, 40 nm, 45 nm, 50 nm and 55 nm in the unit cell of FIG. 23.

FIG. 25 shows a top view of a unit cell in an embodiment.

FIG. 26 shows a top view of a unit cell in an embodiment.

FIG. 27 shows the absorption spectra of the nanowires of radii of 50 nm, 60 nm, 70 nm, 80 nm, 90 nm, 100 nm in the unit cell of FIG. 26.

FIG. 28 shows a top view of a unit cell in an embodiment.

FIG. 29A shows the absorption spectrum of a Si nanowire of radius of 50 nm.

FIG. 29B shows the absorption spectrum of a Si nanowire of radius of 20 nm.

### DETAILED DESCRIPTION

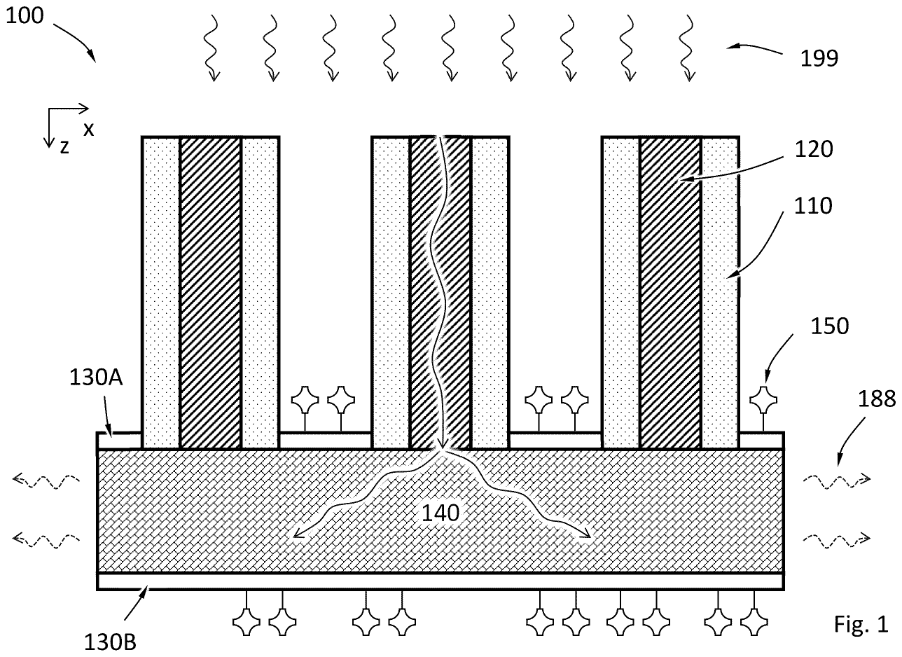

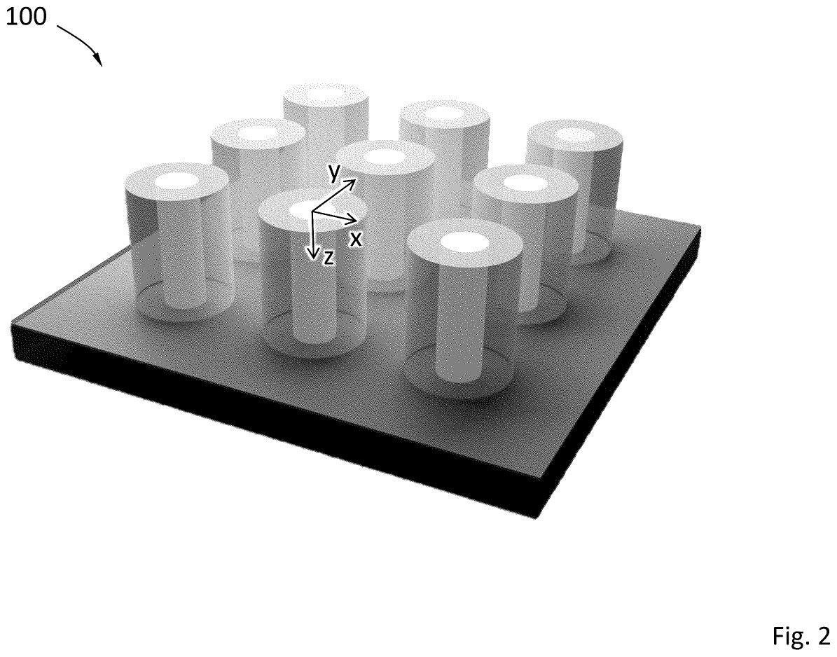

FIG. 1 schematically shows a cross-section of a portion of a device 100. FIG. 2 schematically shows a perspective view of the device 100 in FIG. 1. The device 100 has a substrate 140. The substrate 140 is made of a dielectric material, such as an oxide (e.g., SiO₂). Nanowires are attached to the substrate 140 on at least one surface of the substrate 140. The nanowires are in a periodic array. At least one nanowire has core 120 and a cladding 110 surrounding the core 120. The core 120 may be cylindrical in shape. The core 120 is a semiconductor (e.g., Si). The cladding 110 is a dielectric material such as an oxide (e.g., SiO₂). The material of the cladding 110 and the material of the substrate 140 may or may not be the same. The cladding 110 may have a uniform thickness in the radial direction of the core 120. For convenience, a coordinate system is defined as follows. The plane in FIG. 1 is the x-z plane. The y axis extends into the plane of FIG. 1. The x, y and z axes are mutually perpendicular. The z axis is perpendicular to the substrate 140. The x axis is parallel to the substrate 140. In this coordinate system, the core 120 extends along the z axis.

There is a metal layer 130A on the surface of the substrate from which the nanowires extend. The metal layer 130A does not extend between the nanowires and the substrate 140. Namely, the core 120 and the cladding 110 are in direct physical contact with the substrate 140. There is another metal layer 130B on the surface of the substrate opposite from the metal layer 130A.

The device 100 is configured to receive light 199 along the z axis. This does not mean that the light 199 must propagate exactly along the z axis. The light 199 instead may propagate along one or more directions not entirely in the x-y plane. The light 199 is not limited to visible light. The light 199 may be infrared or ultraviolet or generally electromagnetic waves of other wavelength ranges. The light 199 may be a “broad band” light, meaning its wavelength range may be broad. For example, the light 199 may be a white light. The device 100 may have materials 150 (e.g., biomolecules) present on the metal layer 130A, the metal layer 130B or both. Output light 188 from the device 100 may be detected from a sidewall of the substrate 140.

According to Maxwell's equations, if the light 199 incident on the nanowires exactly along the z axis, the electric field vector of the light 199 has only Ex and Ey field components, respectively along the x axis and the y axis. The nanowires act as absorbing waveguides that both filter and confine the light 199 as it propagates along the nanowires. When the light 199 reaches the substrate 140, which has a smaller refractive index than the core 120, the light 199 diffracts and diverges into the substrate 140 and thus has light components propagating in the substrate 140 along the x axis and the y axis.

The light component propagating along the x axis has field components Ey and Ez of the electric field. The field components Ey and Ez are respectively along the y axis and the z axis. The light component propagating along the y axis has field components Ex and Ez of the electric field. The field components Ex and Ez are respectively along the x axis and the z axis.

The light component propagating along the x axis or the y axis interact with surface plasmons in the metal layer 130A and the metal layer 130B. The light component propagating along the z axis does not interact with the surface plasmons in the metal layer 130A and the metal layer 130B.

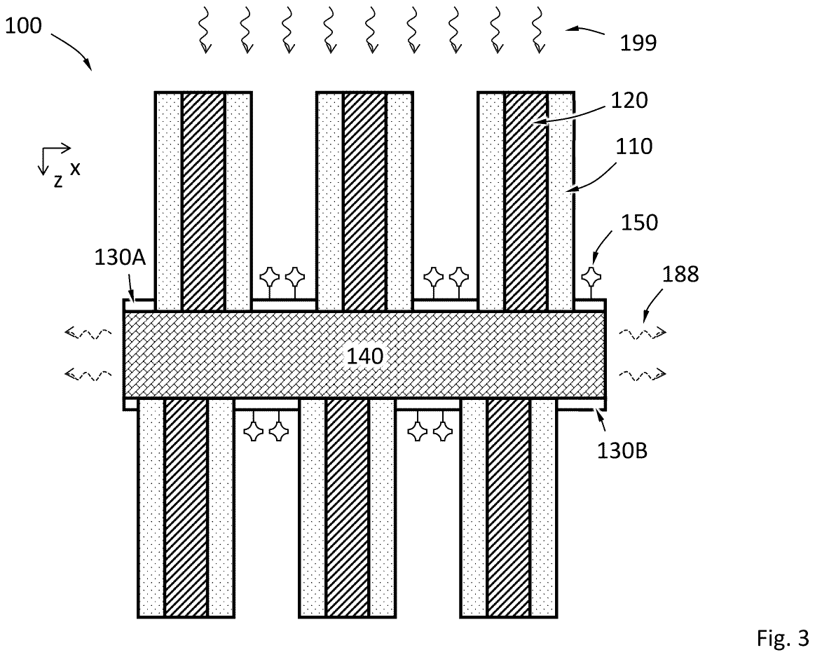

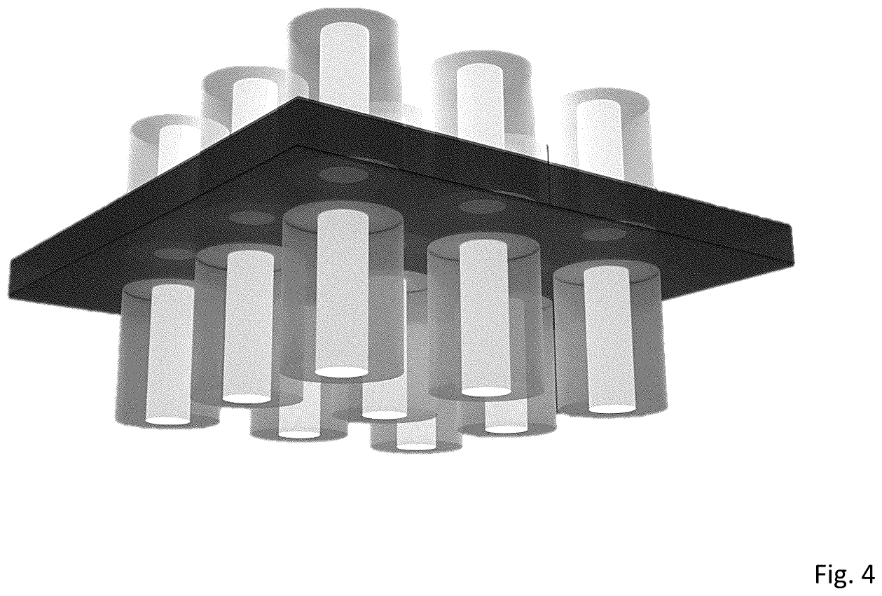

FIG. 3 shows a variant of the device 100 where nanowires are attached to the substrate 140 on both surfaces of the substrate 140. The metal layer 130B does not extend between the nanowires and the substrate 140. FIG. 2 schematically shows a perspective view of the device 100 in FIG. 1. The nanowires on both surfaces of the substrate 140 do not have to be aligned. As shown in FIG. 3, the nanowires on both surfaces of the substrate 140 are not aligned.

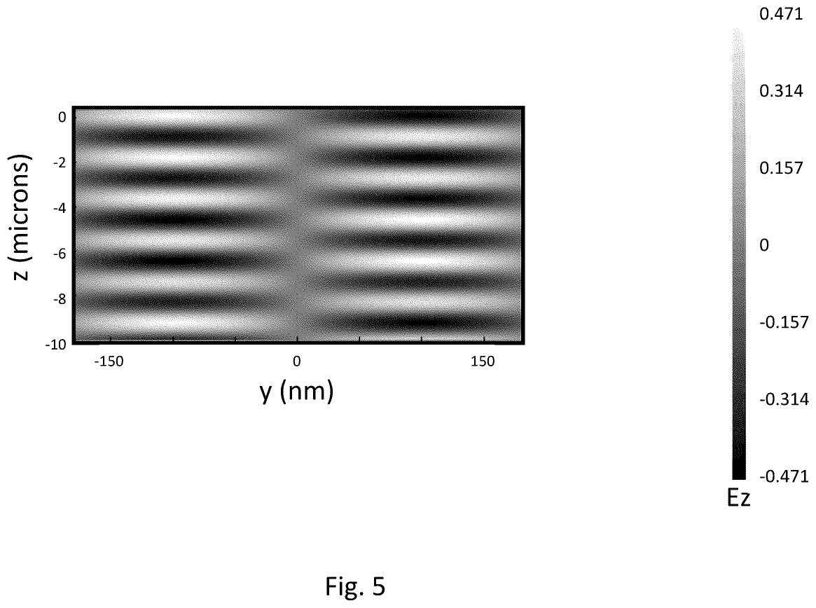

FIG. 5 shows the electric field component along the z axis (i.e., Ez) in a cross section in the y-z plane of the substrate 140, of the light component propagating along the y axis. Ez having maxima and minima at the metal layer 130A and the metal layer 130B indicates that Ez can support a plasmonic wave since metals cannot support longitudinal (aligned along the surface or tangential) fields. Ez having only one maximum and only one minimum shows the relationship between the pitch of the nanowires and the propagation mode of the output light 188.

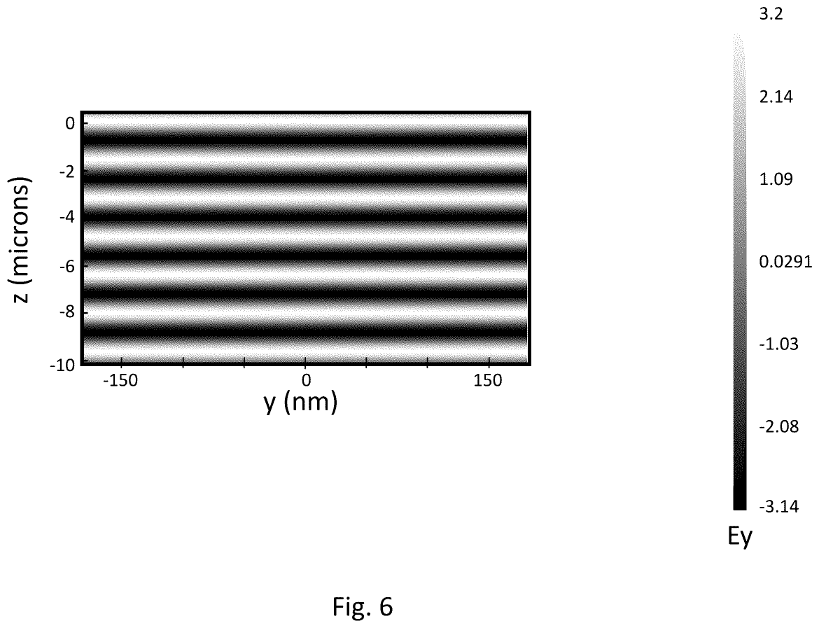

FIG. 6 shows the electric field component along the y axis (i.e., Ey) in a cross section in the y-z plane of the substrate 140, of the light component propagating along the x axis. Ey going to zero at the metal layer 130A and the metal layer 130B indicates Ey cannot support a plasmonic wave since metals cannot support longitudinal (aligned along the surface or tangential) fields.

The materials 150 (e.g., biomolecules) present on the metal layer 130A, the metal layer 130B or both may alter the resonance conditions of Ez. The output light 188 may be filtered to keep Ez and attenuate Ex and Ey. The output light 188 may be used for detection of the materials 150.

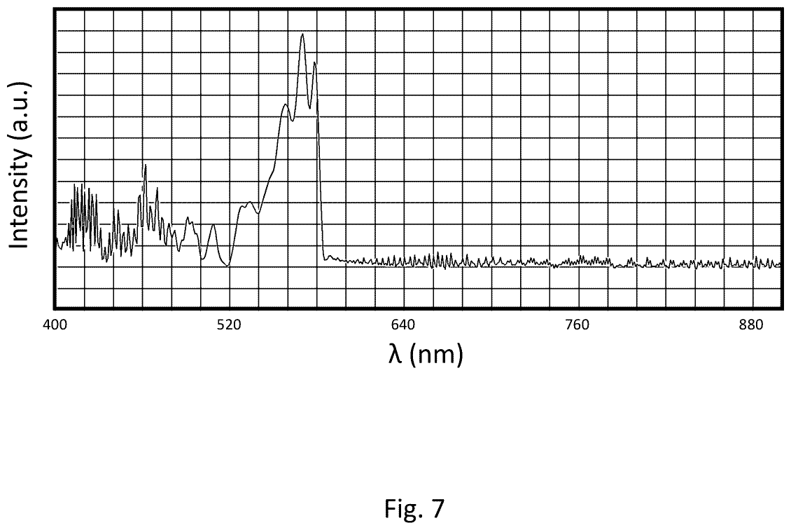

FIG. 7 shows an example of the spectrum of the output light 188 from the substrate 140, where the substrate 140 has a thickness of 100 microns and the light 199 does not have distinct peaks. The spectrum of the output light 188 has distinct peaks despite the absence of distinct peaks in the light 199. The positions of the peaks depend on the diameter and the pitch of the nanowires. The positions of the peaks are sensitive to the plasmonic charge oscillations in the metal layer 130A and the metal layer 130B and therefore may be used for detecting the materials 150 on the metal layer 130A and the metal layer 130B.

The device 100 may also be used as an optical coupler to a slab waveguide resonator. The nanowires could be placed at any position along a slab waveguide (as the substrate 140) and cover only a portion of the slab waveguide. The nanowires may couple a broad band input light to obtain a desired output light with a narrow spectrum out of the slab waveguide. The nanowires may be used as a confining waveguide to pump a doped oxide slab waveguide laser. In this embodiment, the sidewall surfaces of the substrate 140 may be partially or fully mirrored (i.e., with a partially or fully reflective film applied).

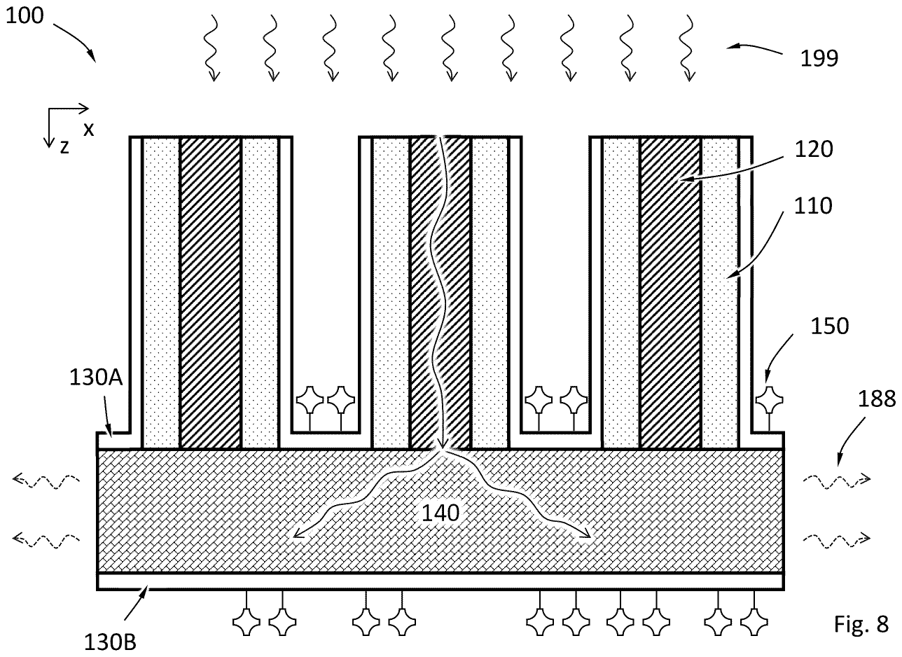

FIG. 8 shows a variant of the device 100 where the metal layer 130A extends to the sidewall of the cladding 110. In other words, the metal layer 130A is not only on the surface of the substrate 140 but also surrounds the cladding 110. The metal layer 130A may or may not cover the entire sidewall of the cladding 110. The metal layer 130B may also extend to the sidewall of the cladding 110 of any nanowires extending from the surface to the substrate 140. The surface of the nanowires receiving the light 199 preferably is free of the metal layer 130A but may have a thin metal layer.

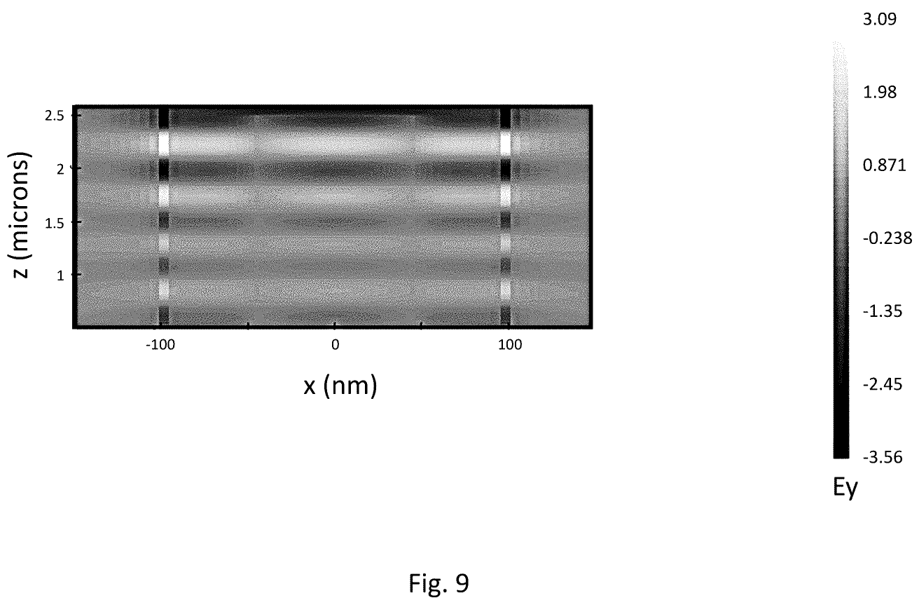

FIG. 9 shows the electric field component along the y axis (i.e., Ey) in a cross section in the y-z plane of the substrate 140, of the light component propagating along the x axis, in the variant shown in FIG. 8. In contrast to FIG. 6 where Ey does not support a plasmonic wave, here in FIG. 9, Ey does support a plasmonic wave in the portion of the metal layer 130A parallel to the z axis. The high-contrast bands in FIG. 9 show plasmonic waves propagating in the portion of the metal layer 130A parallel to the z axis. The variant in FIG. 9 increases the utilization of the light 199 compared to the variants in FIG. 1 and FIG. 3.

Semiconductor nanowires (e.g., Si nanowire) can selectively filter broad band illumination into narrow bands. The filtering behavior depends on the radii of the nanowires. This behavior is due to the highly dispersive (complex index of refraction being a strong function of wavelength of incident light) property of the semiconductor. The light in the semiconductor nanowire is a strongly guided wave that is surrounded by an evanescent field that decays exponentially outside the physical boundary of the semiconductor nanowire. There may be a linear relationship between the nanowire radius and the position of its absorption peak when the nanowire is not coupled to other nanowires (i.e., the evanescent field of the nanowire not overlapping with the evanescent fields of the other nanowires).

As the spacing between nanowires decreases and the evanescent fields start to overlap, the behavior of the nanowires starts to deviate from that of uncoupled nanowires. The coupling of the nanowires may be used to control the absorption peak width of the nanowires.

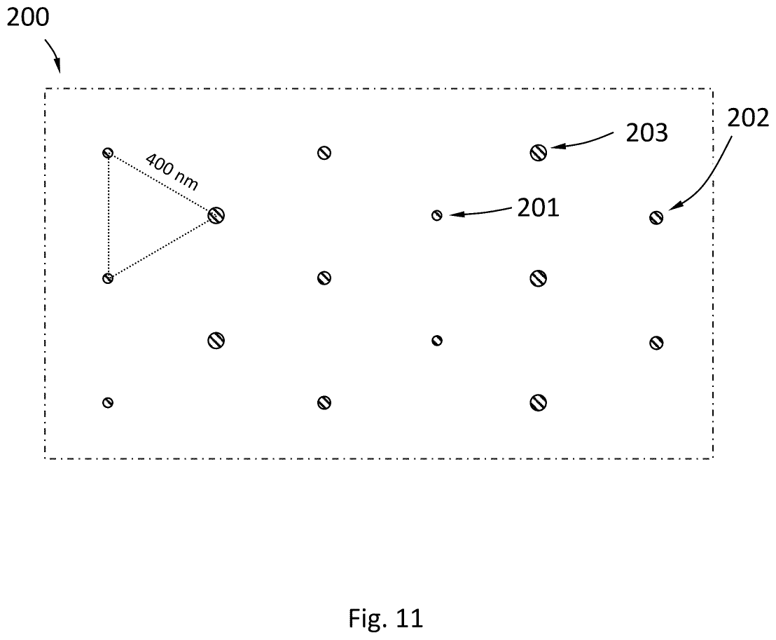

Due to the exponentially decaying nature of the evanescent field, spacing less than the position (in wavelength) of the absorption peak leads to strong coupling of the nanowires. FIG. 11 schematically shows the absorption spectrum of an array of silicon nanowires of radius of 45 nm and length of 1 micron. As the pitch decreases, the coupling increases. With increasing coupling, the absorption peak tends to become higher (i.e., absorption becoming stronger), the position of the absorption peak tends to shift towards shorter wavelengths, and the absorption peak tends to become wider in the shorter wavelengths side (i.e., the profile of the absorption peak changes from a narrow band to a low pass filter).

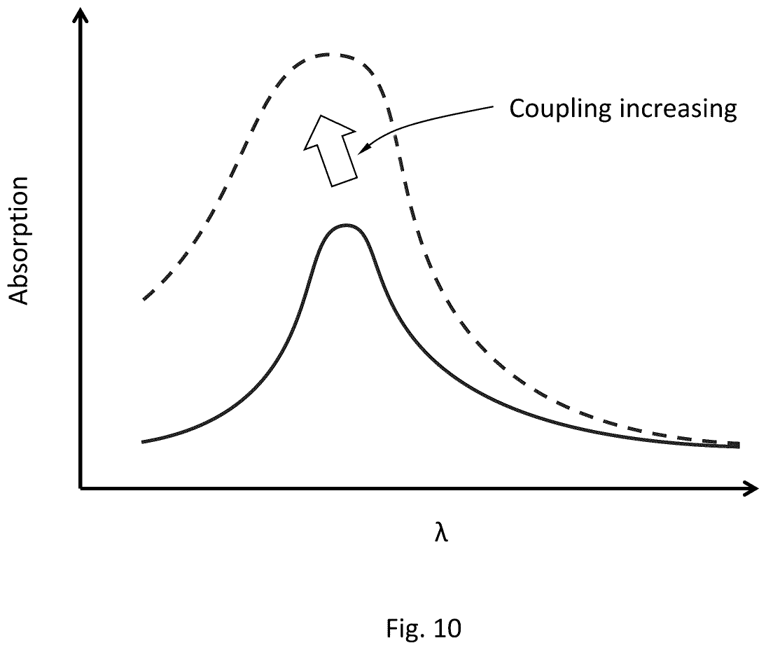

When nanowires of the same radius are within their evanescent fields, their absorption becomes broader, as shown in FIG. 10. Placing nanowires of closely spaced radii (i.e., with closely spaced absorption peaks) next to one another, in contrast, narrows the absorption peaks. This is because nanowires whose evanescent fields overlap share the light incident on them and each nanowire absorbs the wavelengths it resonates with from the light as dictated by its singleton bandwidth. This effect can be used to design multispectral image sensors, with little wasted light and very high external quantum efficiency. When a set of nanowires with different radii are chosen appropriately and positioned such that nearest neighbor radii are within each other's evanescent fields, all available light is parceled out and absorbed. In other words, the response of each nanowire diagonalizes itself to a significant degree relative to its neighbors.

FIG. 11 shows an example of an array 200 of nanowires 201 of a radius of 30 nm, nanowires 202 of a radius of 40 nm and nanowires 203 of a radius of 50 nm, to demonstrate this effect. The nanowires 201, the nanowires 202 and the nanowires 203 are in a triangular lattice as shown, with 400 nm center-to-center spacing between nearest nanowires. The choice of these three radii of 30 nm, 40 nm and 50 nm is not accidental. Their absorption spectra match the CIE tristimulus eye response curves.

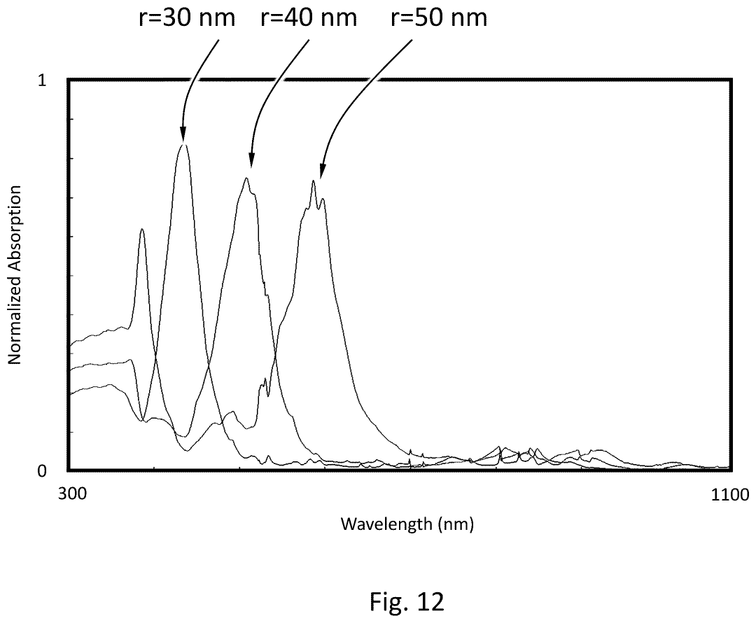

FIG. 12 shows the absorption spectra of the nanowires 201, the nanowires 202 and the nanowires 203. The absorption peaks of these nanowires are narrowed due to coupling among these nanowires.

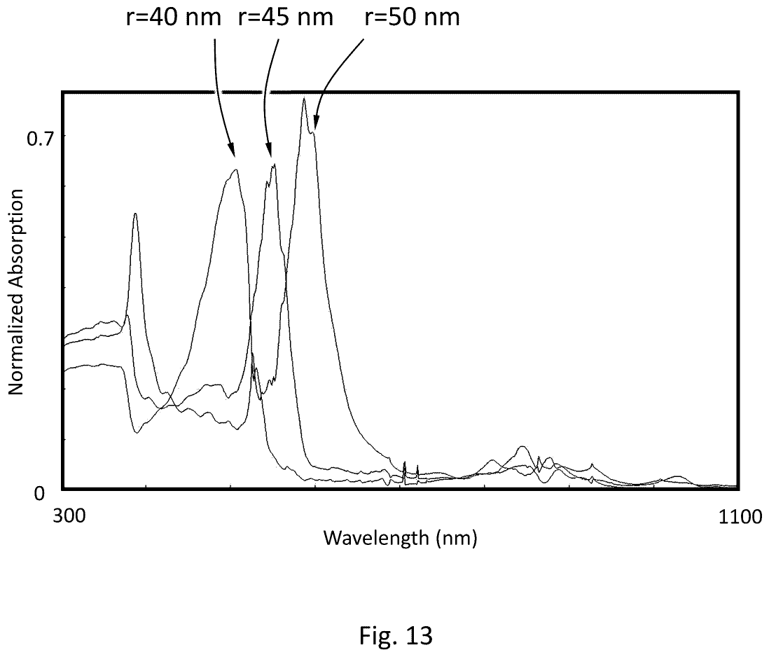

FIG. 13 shows the absorption spectra of the nanowires in another triangular lattice that is the same as the triangular lattice in FIG. 11, except the radii of the nanowires are 40 nm (instead of 30 nm), 45 nm (instead of 40 nm) and 50 nm, respectively.

There may be nanowires of more than three radii in a lattice. In an example, each nanowire has an adjacent nanowire with a radius of one increment above or below the each nanowire.

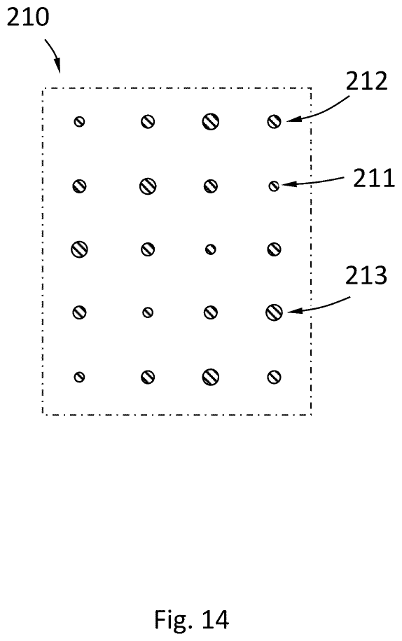

FIG. 14 shows an example of an array 210 of nanowires 211 of a radius of 30 nm, nanowires 212 of a radius of 40 nm and nanowires 213 of a radius of 50 nm, in a square lattice. The nearest neighbors of each nanowire have radii of one increment (which is 10 nm in this example) higher or lower. For example, the nearest neighbors of one of the nanowires 213 are not one of the nanowires 211 because their radii differ by more than one increment. The absorption spectra of the nanowires in this example show three distinct narrowed absorption peaks, similar to those in FIG. 12.

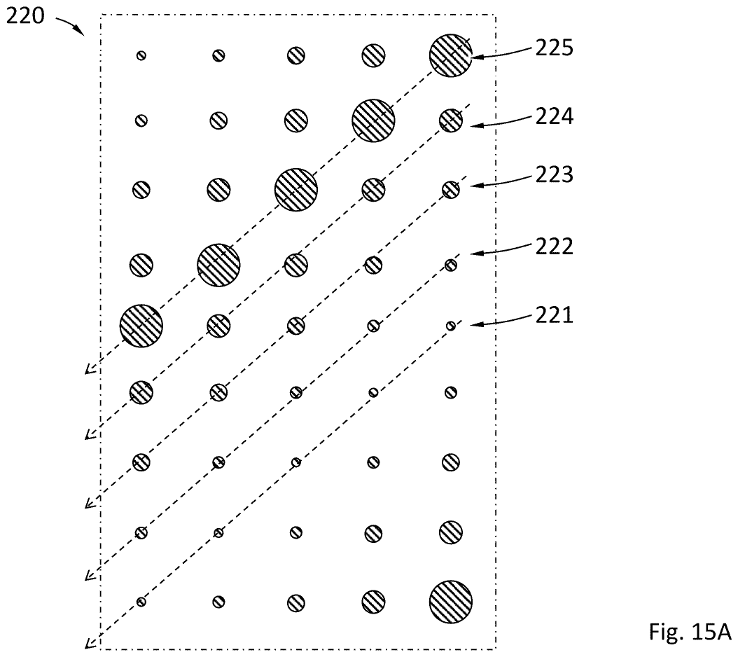

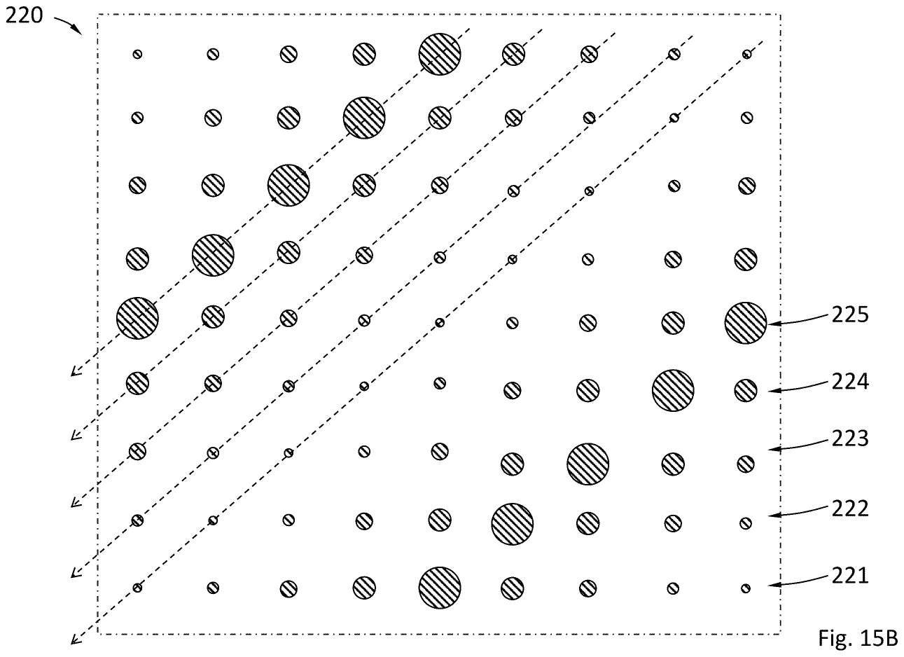

FIG. 15A shows an example of an array 220 of nanowires 221 of a radius of 30 nm, nanowires 222 of a radius of 40 nm, nanowires 223 of a radius of 50 nm, nanowires 224 of a radius of 60 nm, and nanowires 225 of a radius of 70 nm, in a square lattice. The nearest neighbors of each nanowire have radii of one increment (which is 10 nm in this example) higher or lower. For example, the nearest neighbors of one of the nanowires 223 are not one of the nanowires 221 or one of the nanowires 225 because their radii differ by more than one increment. The absorption spectra of the nanowires in this example show five distinct narrowed absorption peaks.

FIG. 15B shows an alternative example of an array 220 of nanowires 221 of a radius of 30 nm, nanowires 222 of a radius of 40 nm, nanowires 223 of a radius of 50 nm, nanowires 224 of a radius of 60 nm, and nanowires 225 of a radius of 70 nm, in a square lattice. The nearest neighbors of each nanowire have radii of one increment (which is 10 nm in this example) higher or lower. For example, the nearest neighbors of one of the nanowires 223 are not one of the nanowires 221 or one of the nanowires 225 because their radii differ by more than one increment. The absorption spectra of the nanowires in this example show five distinct narrowed absorption peaks.

In some scenarios, reading the signals from individual nanowires is not necessary. Instead, the signals from nanowires of the same radius are summed. The diagonal arrows represent paths of summing and reading the sums.

By designing the spacing, the radii and the spatial arrangement of nanowires, the absorption peak widths of the nanowires may be tailored for various applications such as three-color digital cameras, multispectral sensors and solar-blind image sensors (e.g., with nanowires with absorption peaks around 200-300 nm with spacing of about 200 nm).

The nanowires do not need an anti-reflection coating, a micro lens or a color filter. The nanowires may be fabricated using standard CMOS fabrication processes.

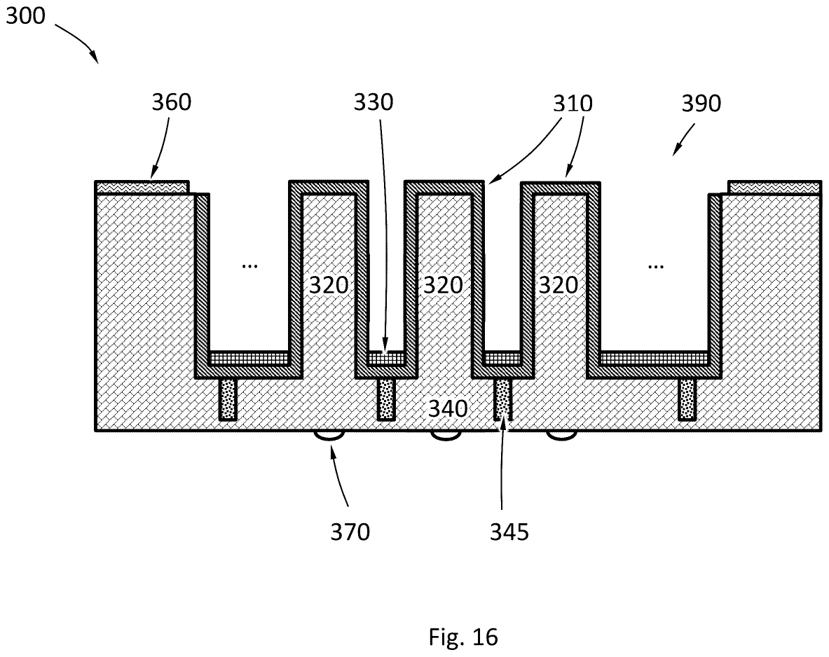

FIG. 16 schematically shows a cross-section of a portion of a device 300. The device 300 includes a substrate 340 with a recess 390 into a surface of the substrate 340. Nanowires 320 are inside the recess 390 and extend from the bottom of the recess 390. In an embodiment, the lattice of the nanowires 320 and the lattice of the substrate 340 are continuous (i.e., the nanowires 320 and the substrate 340 are of the same single crystal). The device 300 has a conformal coating 310 on the bottom of the recess 390, the sidewall of the nanowires 320, the top surface of the nanowires 320, and optionally the sidewall of the recess 390. The device 300 has a light blocking layer 330 at the bottom of the recess 390 among the nanowires 320 and over the conformal coating 310. In other words, the light blocking layer 330 is separated from the substrate 340 by the conformal coating 310. The light blocking layer 330 preferably is not on the sidewall or the top surface of the nanowires 320 but that is not a requirement. The device 300 has an electric contact 360 to the substrate 340. The electric contact 360 may serve as a common electrode for the nanowires 320. The device 300 has bump contacts 370 corresponding to the nanowires 320 and are on the surface of the substrate 340 opposite the recess 390. The device 300 does not need microlenses or color filters. Therefore, in an embodiment, the device 300 does not have microlenses or color filters. The conformal coating 310 and the nanowires 320 form a p-n junction at the interface between the conformal coating 310 and the nanowires 320. In FIG. 16, the p-n junction is continuous and is conformal to the nanowires 320. The device 300 may have optional dielectric filled isolation trenches 345 in the substrate 340. The optional dielectric filled isolation trenches 345 help isolating charge carriers from different nanowires 320 to prevent crosstalk.

The substrate 340 may be doped silicon (e.g., n-Si), Ge, InAs or other suitable semiconductor materials. The conformal coating 310 may be a dielectric material (e.g., aluminum oxide, which may be dopant-free aluminum oxide formed by atomic layer deposition). The nanowires 320 may be formed by etching the substrate 340. The nanowires may be coextensive with the depth of the recess 390 or shorter. The light blocking layer 330 may be a metal layer such as an aluminum layer. The electric contact 360 may include a layer of molybdenum oxide in direct contact with the substrate 340 and a layer of metal (e.g., aluminum) on the layer of molybdenum oxide. The electric contact 360 may function as a hole collector. The bump contacts 370 may be a layer of LiF and a layer of metal on the layer of LiF. The recess 390 may be formed by etching the substrate 340.

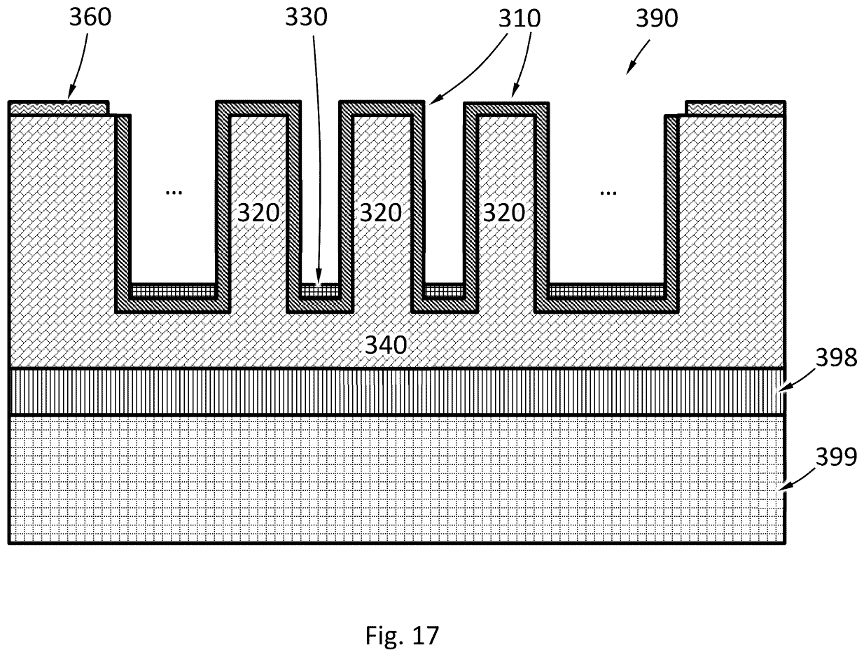

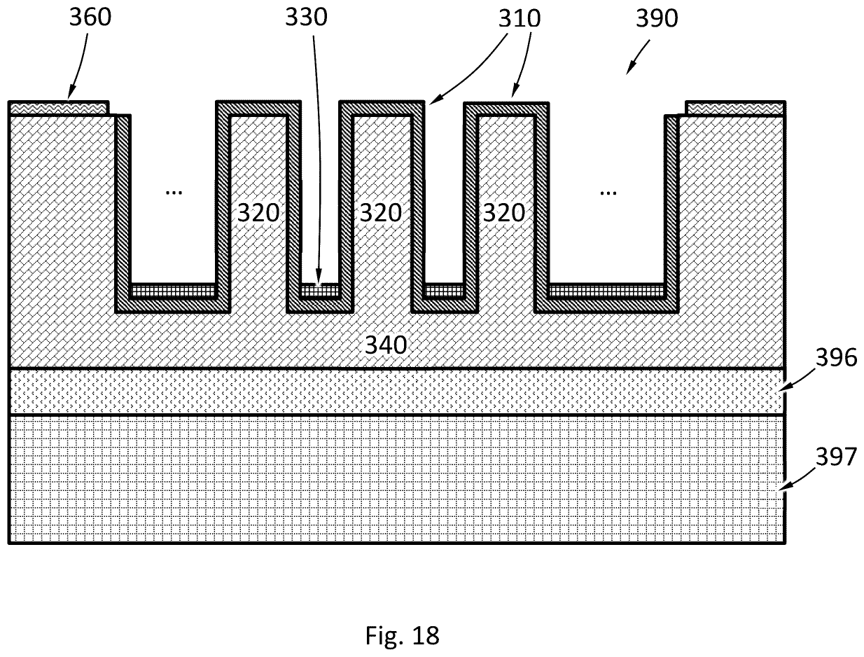

FIG. 17 shows that the device 300 may be connected to a signal processing circuit 399 using interconnects 398. The signal processing circuit 399 may be any existing or to-be-developed circuit that can process the signals read from the nanowires 320. For example, the signal processing circuit 399 may be a circuit fabricated using CMOS technology. The device 300, the interconnects 398 and the signal processing circuit 399 may be connected by wafer bonding or other suitable techniques. FIG. 18 shows that the device 300 may be connected to an array of pixel transistors 396 and a signal processing circuit 397. The device 300, the array of pixel transistors 396 and the signal processing circuit 397 may be connected by wafer bonding or other suitable techniques. Alternatively, the device 300 may be fabricated after the interconnects 398 and the signal processing circuit 399 or the array of pixel transistors 396 and the signal processing circuit 397 are attached to the substrate 340.

The radii and arrangement of the nanowires 320 may be designed to achieve desired response to incident light. In an embodiment, the nanowires 320 are arranged in an array of unit cells. The nanowires 320 of different unit cells are not coupled. The nanowires 320 of the same unit cell are coupled.

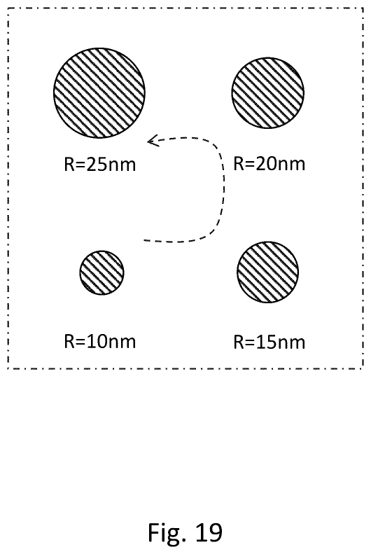

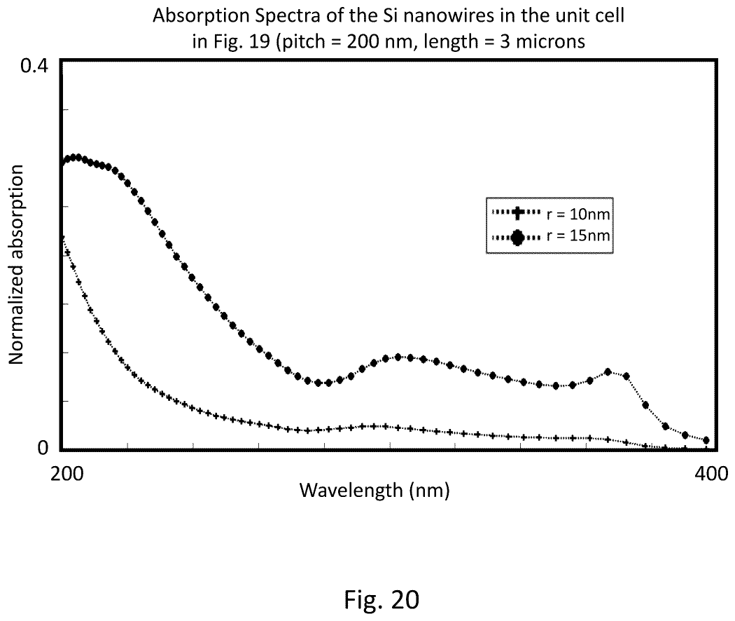

FIG. 19 shows a top view of a unit cell in an embodiment. This unit cell has four nanowires 320 arranged like a “half coil” as shown by the arrow indicating the direction of increasing radii of the nanowires in the unit cell. These four nanowires are silicon nanowires. These four nanowires are arranged at the vertexes of a square. The lengths of these four nanowires may be several microns (e.g., 3 microns). Namely, the four nanowires respectively have radii of 10 nm, 15 nm, 20 nm and 25 nm and are arranged such that (1) the nanowire with a radius of 10 nm is closest to the nanowires of radii of 15 nm and 25 nm, but not to the nanowire of radius of 20 nm; (2) the nanowire with a radius of 15 nm is closest to the nanowires of radii of 10 nm and 20 nm, but not to the nanowire of radius of 25 nm; (3) the nanowire with a radius of 20 nm is closest to the nanowires of radii of 15 nm and 25 nm, but not to the nanowire of radius of 10 nm; and (4) the nanowire with a radius of 25 nm is closest to the nanowires of radii of 10 nm and 20 nm, but not to the nanowire of radius of 15 nm. The pitch (i.e., the closest distance between nearest neighboring nanowires) of the four nanowires in the unit cell is 200 nm. The device 300 with the array in FIG. 19 may be used as a solar-blind UV image sensor. Namely the device 300 with the array in FIG. 19 can form images using ultraviolet light of wavelengths that are totally absorbed by the ozone layer of the earth. Such wavelengths are from about 200 nm to about 300 nm.

FIG. 20 shows the absorption spectra of the nanowires of radii of 10 nm and 15 nm in the unit cell of FIG. 19. The nanowires of radii of 20 nm and 25 nm serve to limit longer wavelength absorption of the nanowires of radii of 10 nm and 15 nm.

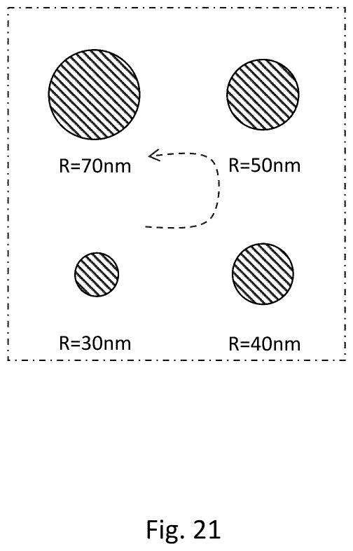

FIG. 21 shows a top view of a unit cell in an embodiment. This unit cell has four nanowires 320 arranged like a “half coil” as shown by the arrow indicating the direction of increasing radii of the nanowires in the unit cell. These four nanowires are silicon nanowires. These four nanowires are arranged at the vertexes of a square. The lengths of these four nanowires may be several microns (e.g., 3 microns). Namely, the four nanowires respectively have radii of 30 nm, 40 nm, 50 nm and 70 nm and are arranged such that (1) the nanowire with a radius of 30 nm is closest to the nanowires of radii of 40 nm and 70 nm, but not to the nanowire of radius of 50 nm; (2) the nanowire with a radius of 40 nm is closest to the nanowires of radii of 30 nm and 50 nm, but not to the nanowire of radius of 70 nm; (3) the nanowire with a radius of 50 nm is closest to the nanowires of radii of 40 nm and 70 nm, but not to the nanowire of radius of 30 nm; and (4) the nanowire with a radius of 70 nm is closest to the nanowires of radii of 30 nm and 50 nm, but not to the nanowire of radius of 40 nm. The pitch (i.e., the closest distance between nearest neighboring nanowires) of the four nanowires in the unit cell is 400 nm. The device 300 with the array in FIG. 21 may be used as an image sensor to detect red, green and blue light (i.e., an RGB image sensor). Specifically, the nanowires of radii of 30 nm, 40 nm, 50 nm respectively absorb blue, green and red light. The nanowire of radius of 70 nm serves to divert absorption of infrared light away from the nanowire of radius of 50 nm.

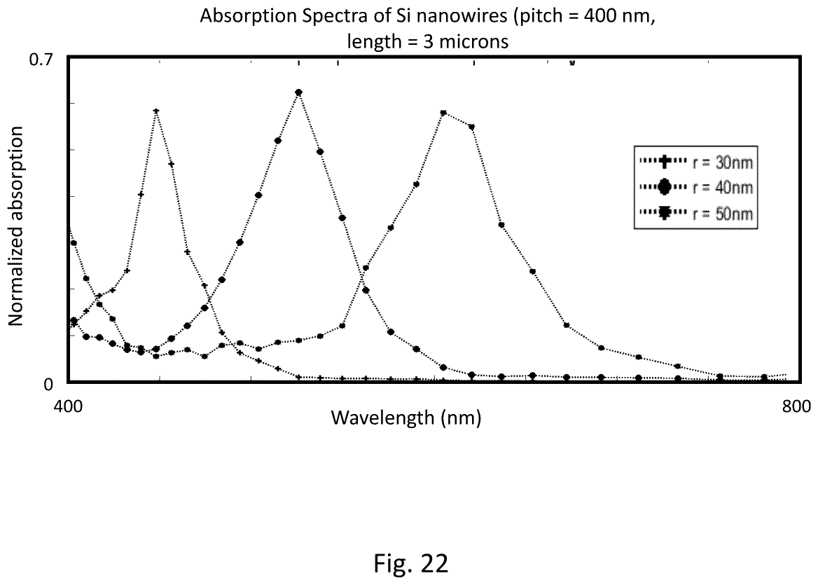

FIG. 22 shows the absorption spectra of the nanowires of radii of 30 nm, 40 nm and 50 nm in the unit cell of FIG. 21.

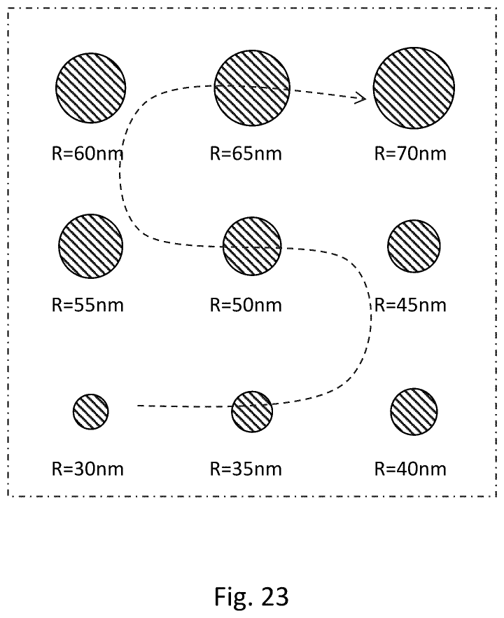

FIG. 23 shows a top view of a unit cell in an embodiment. This unit cell has nine nanowires 320 arranged like a “full coil” as shown by the arrow indicating the direction of increasing radii of the nanowires in the unit cell. These nine nanowires are silicon nanowires. These nine nanowires are arranged at the vertexes of a square, the midpoints of the edges of the square and the center of the square. Namely the nine nanowires are in a square 3-by-3 grid. The lengths of these nine nanowires may be several microns (e.g., 3 microns). Namely, the nine nanowires respectively have radii of 30 nm, 35 nm, 40 nm, 45 nm, 50 nm, 55 nm, 60 nm, 65 nm and 70 nm and are arranged such that (1) the nanowire of radius of 30 nm is closest to the nanowires of radii of 35 nm, 55 nm, but not to the others of the nine nanowires; (2) the nanowire of radius of 35 nm is closest to the nanowires of radii of 30 nm, 40 nm, 50 nm, but not to the others of the nine nanowires; (3) the nanowire of radius of 40 nm is closest to the nanowires of radii of 35 nm, 45 nm, but not to the others of the nine nanowires; (4) the nanowire of radius of 45 nm is closest to the nanowires of radii of 40 nm, 50 nm, 70 nm, but not to the others of the nine nanowires; (5) the nanowire of radius of 50 nm is closest to the nanowires of radii of 35 nm, 45 nm, 55 nm, 65 nm, but not to the others of the nine nanowires; (6) the nanowire of radius of 55 nm is closest to the nanowires of radii of 30 nm, 50 nm, 60 nm, but not to the others of the nine nanowires; (7) the nanowire of radius of 60 nm is closest to the nanowires of radii of 55 nm, 65 nm, but not to the others of the nine nanowires; (8) the nanowire of radius of 65 nm is closest to the nanowires of radii of 50 nm, 60 nm, 70 nm, but not to the others of the nine nanowires; (9) the nanowire of radius of 70 nm is closest to the nanowires of radii of 45 nm, 65 nm, but not to the others of the nine nanowires. The pitch (i.e., the closest distance between nearest neighboring nanowires) of the nine nanowires in the unit cell is 400 nm. The device 300 with the array in FIG. 23 may be used as a multispectral image sensor.

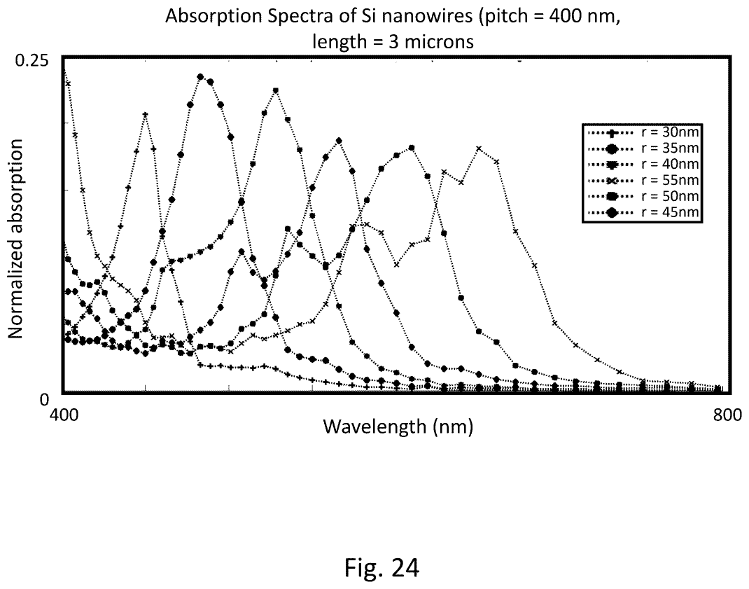

FIG. 24 shows the absorption spectra of the nanowires of radii of 30 nm, 35 nm, 40 nm, 45 nm, 50 nm and 55 nm in the unit cell of FIG. 23.

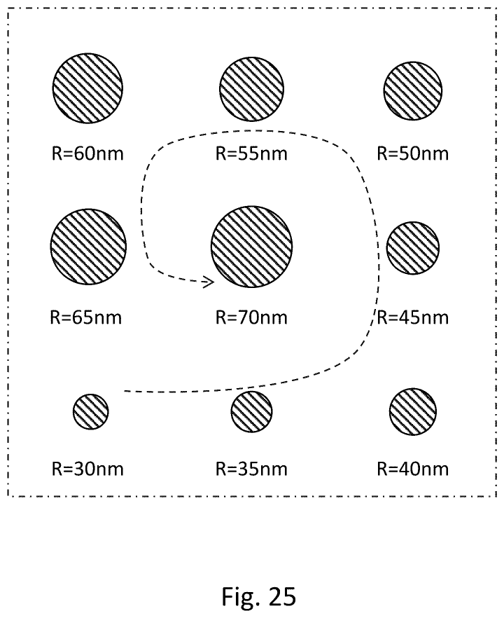

FIG. 25 shows a top view of a unit cell in an embodiment. This unit cell has nine nanowires 320 arranged like a “spiral” as shown by the arrow indicating the direction of increasing radii of the nanowires in the unit cell. These nine nanowires are silicon nanowires. These nine nanowires are arranged at the vertexes of a square, the midpoints of the edges of the square and the center of the square. Namely the nine nanowires are in a square 3-by-3 grid. The lengths of these nine nanowires may be several microns (e.g., 3 microns). Namely, the nine nanowires respectively have radii of 30 nm, 35 nm, 40 nm, 45 nm, 50 nm, 55 nm, 60 nm, 65 nm and 70 nm and are arranged such that (1) the nanowire of radius of 30 nm is closest to the nanowires of radii of 35 nm, 65 nm, but not to the others of the nine nanowires; (2) the nanowire of radius of 35 nm is closest to the nanowires of radii of 30 nm, 40 nm, 70 nm, but not to the others of the nine nanowires; (3) the nanowire of radius of 40 nm is closest to the nanowires of radii of 35 nm, 45 nm, but not to the others of the nine nanowires; (4) the nanowire of radius of 45 nm is closest to the nanowires of radii of 40 nm, 50 nm, 70 nm, but not to the others of the nine nanowires; (5) the nanowire of radius of 50 nm is closest to the nanowires of radii of 45 nm, 55 nm, but not to the others of the nine nanowires; (6) the nanowire of radius of 55 nm is closest to the nanowires of radii of 50 nm, 60 nm, 70 nm, but not to the others of the nine nanowires; (7) the nanowire of radius of 60 nm is closest to the nanowires of radii of 55 nm, 65 nm, but not to the others of the nine nanowires; (8) the nanowire of radius of 65 nm is closest to the nanowires of radii of 30 nm, 60 nm, 70 nm, but not to the others of the nine nanowires; (9) the nanowire of radius of 70 nm is closest to the nanowires of radii of 35 nm, 45 nm, 55 nm, 65 nm. The pitch (i.e., the closest distance between nearest neighboring nanowires) of the nine nanowires in the unit cell is 400 nm. The device 300 with the array in FIG. 25 may be used as a multispectral image sensor in the visible wavelengths.

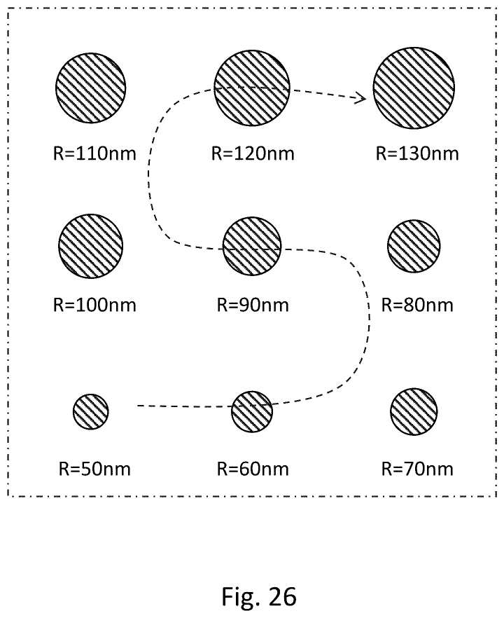

FIG. 26 shows a top view of a unit cell in an embodiment. The unit cell in FIG. 26 is similar to the unit cell in FIG. 23, except that the nanowires are Ge nanowires respectively with radii of 50 nm, 60 nm, 70 nm, 80 nm, 90 nm, 100 nm, 110 nm, 120 nm and 130 nm, a pitch of 1 micron. The device 300 with the array in FIG. 26 may be used as a multispectral image sensor in the near infrared wavelengths.

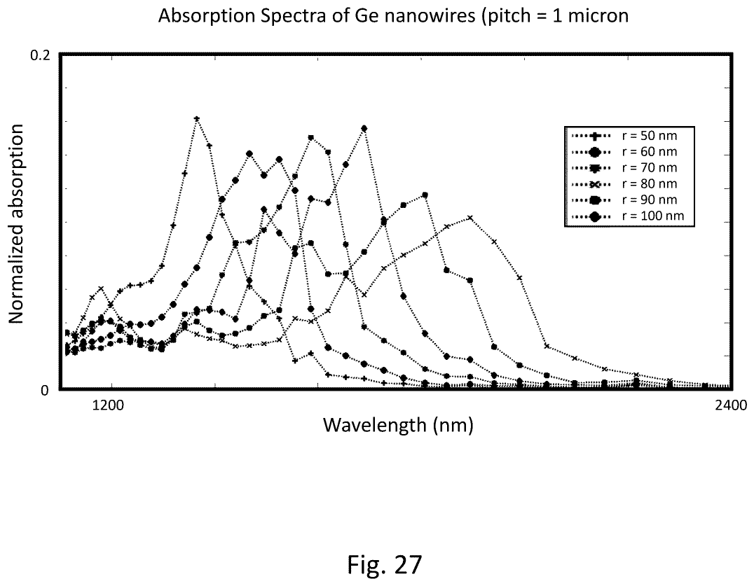

FIG. 27 shows the absorption spectra of the nanowires of radii of 50 nm, 60 nm, 70 nm, 80 nm, 90 nm, 100 nm in the unit cell of FIG. 26.

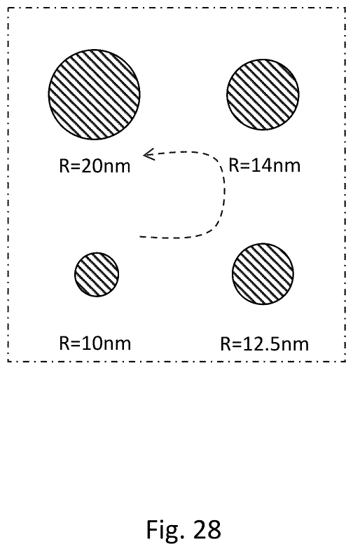

FIG. 28 shows a top view of a unit cell in an embodiment. The unit cell in FIG. 28 is similar to the unit cell in FIG. 19, except that the nanowires respectively have radii of 10 nm, 12.5 nm, 14 nm and 20 nm and a pitch of 200 nm. The device 300 with the array in FIG. 28 may be used as a UV image sensor.

The device 300 may be used to detect ambient light. For example, the device 300 may have nine absorption bands from the Ultraviolet A (UV-A) band (315-400 nm wavelength) to near infrared.

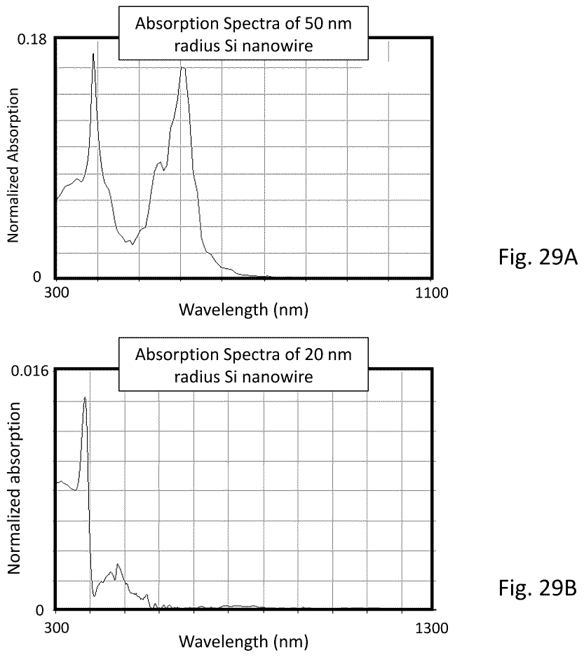

A nanowire in the device 300 may have a higher order absorption peak. The higher order absorption peak is roughly at half of the wavelength of the primary absorption peak. As shown in the example of FIG. 29A, a silicon nanowire of 50 nm radius has its primary absorption peak at about 600 nm and its higher order absorption peak at about 380 nm. FIG. 29B shows that a silicon nanowire of 20 nm radius has its primary absorption peak at about 380 nm. The higher order peak may be used to “subtract” unwanted absorption. For example, when the silicon nanowire of 50 nm radius and the silicon nanowire of 20 nm radius are coupled, the higher order absorption peak at 380 nm in the silicon nanowire of 50 nm is suppressed by the primary absorption peak at 380 nm in the silicon nanowire of 20 nm.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. (canceled)

2. (canceled)

3. (canceled)

4. (canceled)

5. (canceled)

6. (canceled)

7. (canceled)

8. (canceled)

9. (canceled)

10. A device comprising:
a substrate with a recess into a first surface of the substrate;
nanowires inside the recess and extending from a bottom of the recess;
a conformal coating on the bottom of the recess, a sidewall of the nanowires and a top surface of the nanowires; and
a light blocking layer at the bottom of the recess among the nanowires and over the conformal coating;
wherein the conformal coating and the nanowires form a p-n junction at an interface between the conformal coating and the nanowires.

11. The device of claim 10, wherein the nanowires are coextensive with a depth of the recess.

12. The device of claim 10, wherein the p-n junction is continuous and is conformal to the nanowires.

13. The device of claim 10, further comprising dielectric filled isolation trenches in the substrate, wherein the dielectric filled isolation trenches are configured to prevent crosstalk among the nanowires.

14. The device of claim 10, wherein a lattice of the nanowires and a lattice of the substrate are continuous.

15. The device of claim 10, wherein the substrate is a semiconductor.

16. The device of claim 10, wherein conformal coating is on a sidewall of the recess.

17. The device of claim 10, wherein the conformal coating is a dielectric material.

18. The device of claim 10, wherein the conformal coating is aluminum oxide.

19. The device of claim 10, wherein the light blocking layer is not on the sidewall of the nanowires or the top surface of the nanowires.

20. The device of claim 10, further comprising an electric contact to the substrate.

21. The device of claim 20, wherein the electric contact comprises molybdenum oxide.

22. The device of claim 10, further comprising bump contacts corresponding to the nanowires on a second surface of the substrate opposite the first surface.

23. The device of claim 22, wherein the bump contacts comprise LiF.

24. The device of claim 10, wherein the nanowires are arranged in an array of unit cells.

25. The device of claim 24, wherein the nanowires of different unit cells are not coupled.

26. The device of claim 24, wherein the nanowires of a same unit cell are not coupled.

27. The device of claim 24, wherein at least one of the unit cells encompasses a first nanowire of a radius R1, a second nanowire of a radius R2, a third nanowire of a radius R3 and a fourth nanowire of a radius R4;
wherein R4>R3>R2>R1; and
wherein the first nanowire, the second nanowire, the third nanowire, and the fourth nanowire are arranged at the vertexes of a square.

28. The device of claim 27, wherein (1) the first nanowire is closest to the second nanowire and the fourth nanowire but not to the third nanowire; (2) the second nanowire is closest to the first nanowire and the third nanowire but not to the fourth nanowire; (3) the third nanowire is closest to the second nanowire and the fourth nanowire but not to the first nanowire; and (4) the fourth nanowire is closest to the first nanowire and the third nanowire but not to the second nanowire.

29. The device of claim 27, wherein (R2−R1)=(R3−R2).

30. The device of claim 27, wherein R1=10 nm, R2=15 nm, R3=20 nm and R4=25 nm.

31. The device of claim 27, wherein R1=30 nm, R2=45 nm, R3=50 nm and R4=70 nm.

32. The device of claim 27, wherein R1=10 nm, R2=12.5 nm, R3=14 nm and R4=20 nm.

33. The device of claim 24, wherein at least one of the unit cells encompasses nine nanowire: a 1^{st} nanowire of a radius R1, a 2^{nd} nanowire of a radius R2, a 3^{rd} nanowire of a radius R3, a 4^{th} nanowire of a radius R4, a 5^{th} nanowire of a radius R5, a 6^{th} nanowire of a radius R6, a 7^{th} nanowire of a radius R7, an 8^{th} nanowire of a radius R8 and a 9^{th} nanowire of a radius R9;
wherein R9>R8>R7>R6>R5>R4>R3>R2>R1; and
wherein the 1^{st} nanowire, the 2^{nd} nanowire, the 3^{rd} nanowire, the 4^{th} nanowire, the 5^{th} nanowire, the 6^{th} nanowire, the 7^{th} nanowire, the 8^{th} nanowire and the 9^{th} nanowire are in a square 3-by-3 grid.

34. The device of claim 33, wherein (1) the 1^{st} nanowire is closest to the 2^{nd} and 6^{th} nanowires but not to the others of the nine nanowires; (2) the 2^{nd} nanowire is closest to the 1^{st}, 3^{rd} and 5^{th} nanowires but not to the others of the nine nanowires; (3) the 3^{rd} nanowire is closest to the 2^{nd} and 4^{th} nanowires but not to the others of the nine nanowires; (4) the 4^{th} nanowire is closest to the 3^{rd}, 5^{th} and 9^{th} nanowires but not to the others of the nine nanowires; (5) the 5^{th} nanowire is closest to the 2^{nd}, 4^{th}, 6^{th} and 8^{th} nanowires but not to the others of the nine nanowires; (6) the 6^{th} nanowire is closest to the 1^{st}, 5^{th} and 7^{th} nanowires but not to the others of the nine nanowires; (7) the 7^{th} nanowire is closest to the 6^{th} and 8^{th} nanowires but not to the others of the nine nanowires; (8) the 8^{th} nanowire is closest to the 5^{th}, 7^{th} and 9^{th} nanowires but not to the others of the nine nanowires; (9) the 9^{th} nanowire is closest to the 6^{th} and 8^{th}nanowires but not to the others of the nine nanowires.

35. The device of claim 33, wherein (1) the 1^{st} nanowire is closest to the 2^{nd} and 8^{th} nanowires but not to the others of the nine nanowires; (2) the 2^{nd} nanowire is closest to the 1^{st}, 3^{rd} and 9^{th} nanowires but not to the others of the nine nanowires; (3) the 3^{rd} nanowire is closest to the 2^{nd} and 4^{th} nanowires but not to the others of the nine nanowires; (4) the 4^{th} nanowire is closest to the 3^{rd}, 5^{th} and 9^{th} nanowires but not to the others of the nine nanowires; (5) the 5^{th} nanowire is closest to the 4^{th} and 6^{th} nanowires but not to the others of the nine nanowires; (6) the 6^{th} nanowire is closest to the 5^{th}, 7^{th} and 9^{th} nanowires but not to the others of the nine nanowires; (7) the 7^{th} nanowire is closest to the 6^{th} and 8^{th} nanowires but not to the others of the nine nanowires; (8) the 8^{th} nanowire is closest to the 1^{st}, 7^{th} and 9^{th} nanowires but not to the others of the nine nanowires; (9) the 9^{th} nanowire is closest to the 2^{nd}, 4^{th}, 6^{th} and 8^{th} nanowires but not to the others of the nine nanowires.

36. The device of claim 33, wherein (R2−R1)=(R3−R2)=(R4−R3)=(R5−R4)=(R6−R5)=(R7−R6)=(R8−R7).

37. The device of claim 33, wherein R1=30 nm, R2=35 nm, R3=40 nm, R4=45 nm, R5=50 nm, R6=55 nm, R7=60 nm, R8=65 nm and R9=70 nm.
